(19) United States
(12) Patent Application Publication
(10) Pub. No.: US 2024/0055397 A1
(43) Pub. Date: Feb. 15, 2024

(54) THROUGH-SUBSTRATE CONNECTIONS FOR RECESSED SEMICONDUCTOR DIES

(71) Applicant: Micron Technology, Inc., Boise, ID (US)

(72) Inventors: Thiagarajan Raman, Boise, ID (US); Kunal R. Parekh, Boise, ID (US)

(21) Appl. No.: 17/884,484

(22) Filed: Aug. 9, 2022

(51) Int. Cl. H01L 25/065; H01L 23/538; H01L 23/495; H01L 23/492; H01L 23/66; H01L 23/498

(52) U.S. Cl. CPC H01L 25/0655; H01L 23/5386; H01L 23/49575; H01L 23/492; H01L 23/66; H01L 23/49513; H01L 23/49805; H01L 25/18

(57) ABSTRACT

This document discloses techniques, apparatuses, and systems for providing a semiconductor device assembly with through-substrate connections for recessed semiconductor dies. A semiconductor device assembly is described that includes a substrate having a first cavity and a second cavity. A first connective element is located at a side surface of the first cavity and a second connective element is located at a side surface of the second cavity. The semiconductor device assembly include a first semiconductor die and a second semiconductor die implemented at the first cavity and the second cavity, respectively. The first semiconductor die includes a third connective element at an edge surface of the die. The second semiconductor die includes a fourth connective element at an edge surface of the die. The dies are implemented at the cavities and connected through the connective elements to electrically couple the first die to the second die.

### TECHNICAL FIELD

The present disclosure generally relates to semiconductor device assemblies, and more particularly relates to through-substrate connections for recessed semiconductor dies.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of an example semiconductor device assembly.

FIG. 2 illustrates a simplified schematic cross-sectional view of a semiconductor device assembly in accordance with an embodiment of the present technology.

FIGS. 3A-3C illustrate simplified schematic cross-sectional views of a semiconductor device assembly in accordance with an embodiment of the present technology.

FIG. 4 illustrates a simplified schematic perspective view of a semiconductor device assembly in accordance with an embodiment of the present technology.

FIGS. 5-9 illustrate simplified schematic cross-sectional views of a series of fabrication steps of semiconductor device assemblies in accordance with an embodiment of the present technology.

FIG. 10 illustrates a simplified schematic cross-sectional view of a semiconductor device assembly in accordance with an embodiment of the present technology.

FIG. 11 illustrates a simplified schematic cross-sectional view of a semiconductor device assembly in accordance with an embodiment of the present technology.

FIG. 12 illustrates a schematic view showing a system that includes a semiconductor device assembly configured in accordance with an embodiment of the present technology.

FIG. 13 illustrates an example method for fabricating a semiconductor device assembly in accordance with an embodiment of the present technology.

### DETAILED DESCRIPTION

Semiconductor devices are integrated in many devices to implement memory cells, processor circuits, imager devices, and other functional features. As more applications for semiconductor devices are discovered, designers are tasked with creating improved devices that can perform a greater number of operations per second, store greater amounts of data, or operate with a higher level of security. To accomplish this task, designers continue to develop new techniques to increase the number of circuit elements on a semiconductor device without simultaneously increasing the size of the device. This development, however, may not be sustainable due to various challenges that arise from designing semiconductor device with high circuit density. Thus, additional techniques may be required to continue the growth in capability of semiconductor devices.

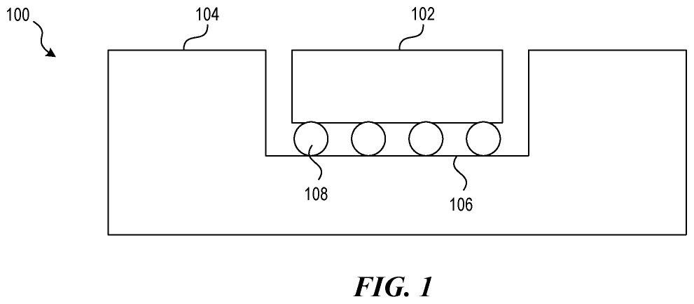

One such technique is to implement multiple semiconductor dies within a single package. These multiple dies may be stacked to increase the number of circuit elements within the package without increasing a footprint (e.g., horizontal area) of the device. Stacked semiconductor devices (e.g., three-dimensional interface (3DI) packaging solutions) are often implemented as a set of multiple semiconductor dies disposed on a semiconductor wafer. While stacked semiconductor devices may enable additional dies to be implemented without increasing the device footprint, these designs may introduce spatial constraints in the vertical direction due to, for example, the thickness of the device in which they are implemented. To satisfy these spatial constraints, various techniques may be performed to minimize the height of a designed semiconductor device. Many of these solutions, however, may fail to provide adequate connections to enable the semiconductor device to efficiently communicate with one or more internal or external components implemented. One such semiconductor assembly is illustrated by way of example in FIG. 1.

As can be seen with reference to FIG. 1, a semiconductor device assembly 100 includes a semiconductor die 102 implemented in a recessed cavity 106 of a substrate 104. The die 102 may couple to the substrate 104 at a bottom surface of the cavity 106. The bottom surface of the die 102 may include contact pads (e.g., conductive pads) that couple directly or indirectly to internal or external traces, vias, lines, and other electrical connection structures to provide functionality to the dies 102 (e.g., power, ground, input/output (I/O) signals). The substrate 104 may similarly include contact pads at the bottom surface of the cavity 106 that couple to internal traces, vias, or lines, or to external connections, for instance, located on a printed circuit board (PCB).

The contact pads of the die 102 and the substrate 104 may couple through interconnects 108 (e.g., solder joints, direct bonds). Given that the contact pads are located at the bottom surface of the cavity 106, the interconnects 108 may be implemented between the bottom surface of the die 102 and the bottom surface of the cavity 106 (e.g., on a top surface of the substrate 104). To provide connectivity between circuitry at a top surface and the contact pads located at the bottom surface of the die 102, the die 102 may include through-silicon vias (TSVs) (not shown) that extend through the die 102. The interconnects 108 may then connect the circuitry on the die 102 to routing circuitry in the substrate 104 or to any other circuitry external to the substrate 104 (e.g., on a PCB). In this way, the die 102 may transmit and receive signaling to/from other components coupled to or assembled on the substrate 104.

In general, TSVs may be surrounded by inactive areas in the die 102 where circuitry may not be disposed due to possible interferences from the TSVs. Moreover, the TSVs may extend through multiple layers of circuitry such that circuit routing on these layers becomes increasingly more complex. In some designs, large quantities of TSVs may be required to provide sufficient connectivity to enable the die to operate properly. Thus, semiconductor device designs that rely on TSVs to provide sufficient connectivity for the die to operate may be inefficient, complex, or costly.

To overcome these deficiencies and others, the technology disclosed herein may utilize lateral connections to connect multiple dies coupled to a substrate at recessed cavities. The dies may include connective structures at an edge surface that couple to a connective structure on the side surface of the cavities. The connective structures at the substrate may be connected by lateral circuitry that extends laterally through the substrate. In this way, the dies may communicate through circuitry internal to the substrate without having to route through vertical connective structures in the dies (e.g., TSVs). As a result, an efficient, connected semiconductor device may be assembled.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a printed circuit board (PCB) or wafer-level substrate, a die-level substrate, or another die for die-stacking or 3DI applications.

A person having ordinary skill in the relevant art will recognize that suitable steps of the methods described herein can be performed at the wafer level or at the die level. Thus, although some examples may be illustrated or described with respect to dies or wafer, the technology disclosed herein may apply to dies or wafers. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

As used herein, the terms “vertical,” “lateral,” “upper” and “lower” can refer to relative directions or positions of features in the semiconductor die assemblies in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down and left/right can be interchanged depending on the orientation.

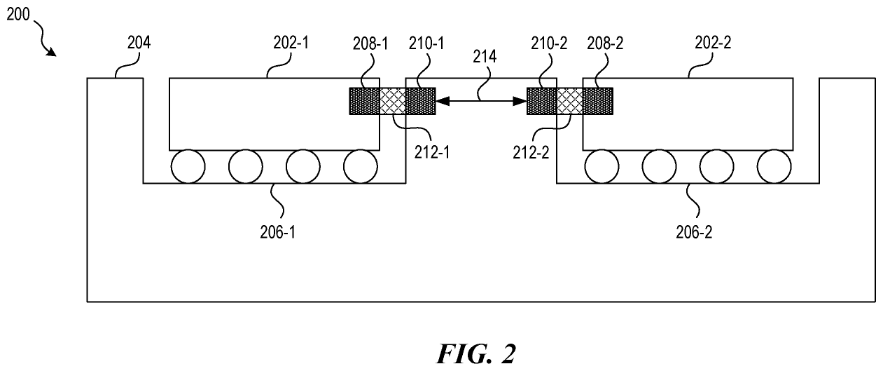

FIG. 2 illustrates a simplified schematic cross-sectional view of a semiconductor device assembly 200 in accordance with an embodiment of the present technology. The semiconductor device assembly 200 includes semiconductor dies 202 (e.g., die 202-1 and 202-2) assembled onto a substrate 204 at multiple cavities 206 (e.g., cavity 206-1 and 206-2). The dies 202 may include connective elements 208 (e.g., connective element 208-1 and 208-2) exposed at an edge surface of the dies 202 and coupled directly or indirectly to circuitry on the dies 202 through internal or external traces, vias, lines, and other electrical connection structures. The substrate 204 may similarly include connective elements 210 (e.g., connective element 210-1 and 210-2) exposed at a side surface of the cavities 206. The connective elements 210 may couple through circuitry internal to the substrate 204 (e.g., traces, vias, lines, and other electrical connection structures) to enable electrical signals to be carried between the connective elements 210.

The connective elements 208 and the connective elements 210 may be coupled through one or more interconnects 212 (e.g., interconnect 212-1 and 212-2), which may be implemented as physical structures coupling the dies 202 and the substrate 204 or a contactless coupling (e.g., optical connection, inductive coupling) between the dies 202 and the substrate 204. In general, however, the interconnects 212 may electrically couple the dies 202 and the substrate 204 to enable through-substrate connectivity between the dies 202. With reference to FIG. 1, this coupling 214 is shown as an arrow through the substrate 204 between the connective elements 210.

In addition to the coupling 214 between the dies 202, the dies 202 may couple to the substrate 204 at the lower surface. In some implementations, the dies 202 may include contact pads (e.g., conductive pads) (not shown) at a lower surface that couple directly or indirectly to circuitry on the dies 202 through internal or external traces, vias, lines, and other electrical connection structures. As a non-limiting example, the dies 202 may include TSVs that couple circuitry at the upper portion of the dies 202 to contact pads at the lower surface. Similar to the dies 202, contact pads (not shown) may be located at a bottom surface of the cavities 206 (e.g., at the upper surface of the substrate 204 in the cavities 206), and these contact pads may couple to internal or external electrical connection structures. For instance, the contact pads on the substrate 204 may couple (e.g., indirectly through internal circuitry) to external connections at a silicon interposer or printed circuit board (PCB). The dies 202 and the substrate 204 may couple through solder joints or other connection structures at their respective contact pads to enable the dies 202 to transmit and receive electrical signaling to/from other connected components internal or external to the substrate 204.

In contrast to the semiconductor device assembly illustrated in FIG. 1, a semiconductor device assembly in accordance with an embodiment of the present technology may be provide improved connectivity across the device. For example, dies 202 may couple through the substrate 204 at connective elements 208 located on the edge surface of the dies 202. In other semiconductor device, the portion of the substrate 204 between cavities 206 may be left undeveloped, if multiple cavities 206 are implemented in the substrate 204 at all. Thus, the semiconductor device described herein may leverage unused portions of the substrate 204 to provide increased connectivity between the various connected components.

Moreover, the coupling 214 may enable direct communication between the dies 202 without routing through other circuitry internal to the substrate 204 or located at an external component, for instance, at a PCB. Other semiconductor devices may utilize external circuitry located at a silicon interposer or PCB to route signals between various components. This implementation may require signals to route through complex circuitry and in some cases, multiple components, to transmit signaling between dies 202 assembled onto the substrate 204. In contrast, a semiconductor device in accordance with an embodiment of the present technology may include a substrate 204 having internal connections dedicated to communications between a particular set of circuit components (e.g., the dies 202). As a result, the semiconductor device may enable low-latency communication between the dies 202.

Additionally, the coupling 214 may be designed such that it does not interfere with other connection structures, such as those routing through a bottom surface of the dies 202 and to the bottom surface of the cavities 206. In this way, a semiconductor device in accordance with an embodiment of the present disclosure may provide direct connections between dies 202 while still providing other connections implemented in other semiconductor devices. Thus, semiconductor devices described herein may provide improved connectivity compared to other semiconductor devices.

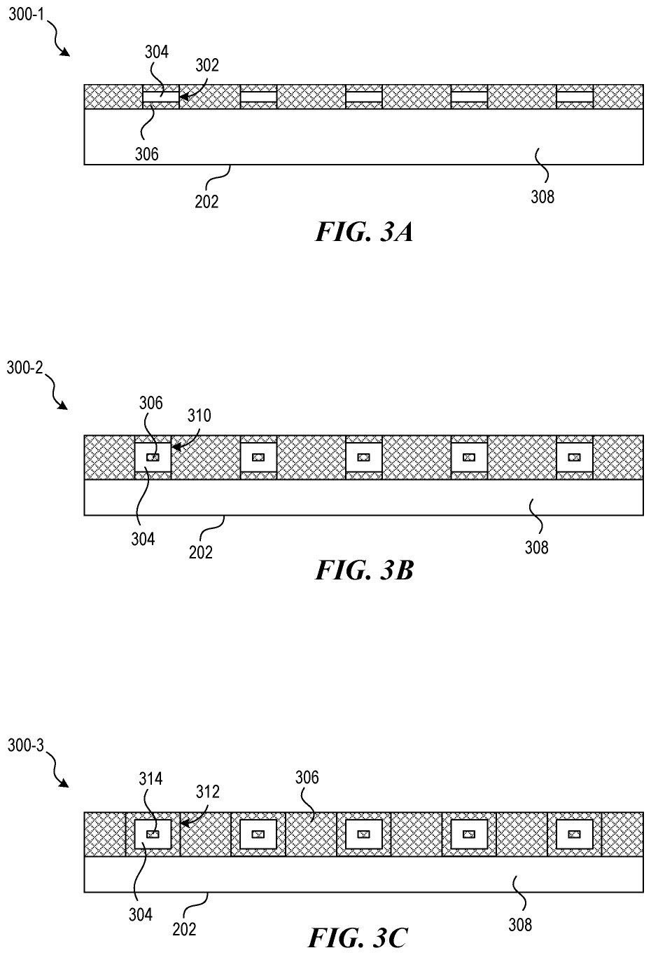

This disclosure now turns to FIGS. 3A-3C to describe various semiconductor dies and the connective elements thereof that may be used to implement a through-substrate connection for recessed semiconductor dies. The cross-sectional views illustrated in FIGS. 3A-3C may correspond to an edge surface of the dies at which connective elements are exposed (e.g., a right edge surface of die 208-1 or a left edge surface of die 208-2 as illustrated in FIG. 2).

Specifically, FIG. 3A illustrates a simplified schematic cross-sectional view of a semiconductor device assembly 300-1, including conductive contacts 302 exposed at the edge surface 308 of the semiconductor die 202. The conductive contacts 302 may be an example of the connective elements 208 illustrated in FIG. 2. The conductive contacts 302 can include one or more layers of conductive material 304 (e.g., copper, gold, silver, aluminum, or an alloy thereof) or dielectric material 306 (e.g., silicon oxide, silicon nitride, silicon carbide, silicon carbon nitride, etc.) to form a conductive contact surface exposed at the edge surface 308 of the die 202. For example, the conductive contacts 302 may include one or more layers of conductive material 304 surrounded by one or more layers of non-conductive, dielectric material 306. To enable the conductive contacts 302 to couple with a conductive connection structure, multiple layers of conductive material 304 may be deposited at the die 202 to create a sufficiently large conductive surface at the edge of the die 202.

The conductive contacts 302 can be at or a distance from the top surface of the die 202. The conductive contacts 302 may be laterally spaced along the edge surface 308 such that the conductive contacts 302 do not interfere with one another. Although shown as a single row of conductive contacts 302, the conductive contacts 302 may be implemented at various heights along the edge surface 308 of the die 202, including multiple conductive contacts 302 located at the same lateral location and different heights (e.g., in multiple rows). Moreover, although illustrated with a particular number of conductive contacts 302, a semiconductor device may include fewer (e.g., 1, 2, 3, or 4) or more (e.g., 10, 100, 1000, etc.) conductive contacts 302. In general, however, the conductive contacts 302 may be implemented at locations that correspond to connective elements at the substrate (e.g., connective elements 210 of the substrate 204).

The conductive contacts 302 can be in electric communication with one or more circuit components of the die 202 through traces within the die 202. For example, the die 202 can include circuitry disposed at the upper portion of the die 202, and traces can extend along the upper portion of the die 202 between the conductive contacts 302 and the circuitry. The conductive contacts 302 can similarly connect with one or more other internal or external components through traces, vias, or lines internal or external to the die 202. To create the conductive contacts 302, layers of material may be deposited on the upper surface of the die 202. For example, layers of conductive material 304 and dielectric material 306 may be deposited at the die 202 to create the conductive contacts 302 or the internal circuitry (e.g., traces, vias, lines, etc.) connecting the conductive contacts 302 to other circuitry internal or external to the die 202.

The conductive contacts 302 can facilitate communication between the die 202 and the substrate 204, and any connections thereof, through the connective elements 210 of FIG. 2. For example, the connective elements 208 may correspond with the connective elements 210, and each of the connective elements 208 and the connective elements 210 may be implemented as one of the conductive contacts 302. As a result, a conductive coupling may be created between the conductive contacts 302 of the die and conductive contacts implemented at the substrate.

FIG. 3B illustrates a simplified schematic cross-sectional view of a semiconductor device assembly 300-2, including inductors 310 exposed at the edge surface 308 of the semiconductor die 202. The inductors 310 may be an example of the connective elements 208 illustrated in FIG. 2. The inductors 310 can include one or more layers of conductive material 304 or dielectric material 306 to form an induction assembly (e.g., an inductor coil). An axis of each of the device inductors 310 (e.g., along a centerline of the inductor coil, normal with the view-plane of FIG. 3B as shown) can be parallel or perpendicular (or any angle therebetween) with the edge surface 308. Like the conductive contacts 302, any number of inductors 310 can be implemented in any arrangement along the edge surface 308 of the die 202.

The inductors 310 can be in electric communication with one or more circuit components of the die 202 through traces within the die 202. For example, the die 202 can include circuitry disposed at the upper portion of the die 202, and traces can extend along the upper portion of the die 202 between the inductors 310 and the circuitry. The inductors 310 can similarly connect with one or more other internal or external components through traces, vias, or lines internal or external to the die 202. To create the inductors 310, layers of material may be deposited on the upper surface of the die 202. For example, layers of conductive material 304 and dielectric material 306 may be deposited at the die 202 to create the inductors 310 or the internal circuitry (e.g., traces, vias, lines, etc.) connecting the inductors 310 to other circuitry internal or external to the die 202.

The inductors 310 can facilitate communication between the die 202 and the substrate 204, and any connections thereof, through the connective elements 210 of FIG. 2. For example, the connective elements 208 may correspond with the connective elements 210, and each of the connective elements 208 and the connective elements 210 may be implemented as one of the inductors 310. The inductors implemented at the substrate can each also include one or more layers of conductive material and/or dielectric material to form and induction assembly. The inductors at the substrate can each include an axis parallel or perpendicular (or any angle therebetween) with a side surface at the cavity of the substrate. The alignment of the inductors 310 located on the die 202 and the inductors located on the substrate can be such that when a current flows through either the inductors 310 or the inductors at the substrate, a corresponding current is induced in the opposing inductor. A surface area of the inductors 310 at the die 202 can be equal to, greater than, or less than a surface area of the opposing inductor. As a result, a conductive coupling may be created between the inductors 310 of the die and inductors implemented at the substrate.

FIG. 3C illustrates a simplified schematic cross-sectional view of a semiconductor device assembly 300-3, optical elements 312 exposed at the edge surface 308 of the semiconductor die 202. The optical elements 312 can include a laser generator 314 (and/or receiver) surrounded by one or more layers of conductive material 304 or dielectric material 306. The laser generator 314 can face outward from the edge surface 308 of the die 202. Like the conductive contacts 302 or the inductors 310, any number of optical elements 312 can be implemented in any arrangement along the edge surface 308 of the die 202.

The optical elements 312 can be in electric communication with one or more circuit components of the die 202 through traces within the die 202. For example, the die 202 can include circuitry disposed at the upper portion of the die 202, and traces can extend along the upper portion of the die 202 between the optical elements 312 and the circuitry. The optical elements 312 can similarly connect with one or more other internal or external components through traces, vias, or lines internal or external to the die 202. To create the optical elements 312, layers of material may be deposited on the upper surface of the die 202. For example, layers of conductive material 304, dielectric material 306, or any other material may be deposited at the die 202 to create the optical elements 312 or the internal circuitry (e.g., traces, vias, lines, etc.) connecting the optical elements 312 to other circuitry internal or external to the die 202.

The optical elements 312 can facilitate communication between the die 202 and the substrate 204, and any connections thereof, through the connective elements 210 of FIG. 2. For example, the connective elements 208 may correspond with the connective elements 210, and each of the connective elements 208 and the connective elements 210 may be implemented as one of the optical elements 312. The optical elements implemented at the substrate can each also include one or more layers of conductive material and/or dielectric material to form and laser generator 314 or the circuitry coupled thereto. The optical elements at the substrate can be located at a side surface at the cavity of the substrate to properly receive or transmit optical signals. The alignment of the optical elements 312 located on the die 202 and the optical elements located on the substrate can be such that when an optical signal is transmitted by the optical elements 312 or the optical elements located on the substrate, the optical signal is received at the opposite optical element. In embodiments that use optical elements 312, adhesive used to couple the die 202 to the substrate (e.g., if any), may be translucent in areas where optical signals propagate. As a result, an optical connection may be created between the optical elements 312 of the die and optical elements implemented at the substrate.

Although not separately interested, the connective elements may instead be implemented as any appropriate component capable of transmitting or receiving a signal. For example, the connective elements at the device or the substrate may be a wireless transceiver. The conductive material 304, the dielectric material 306, or any other material may be utilized to create various components of the transceiver. For example, a transmit or receive array, an antenna, a multiplexer, or any other component may be implemented at the die 202 or the substrate to create a functioning transceiver with a transmitting or receiving element exposed at the edge surface of the die 202.

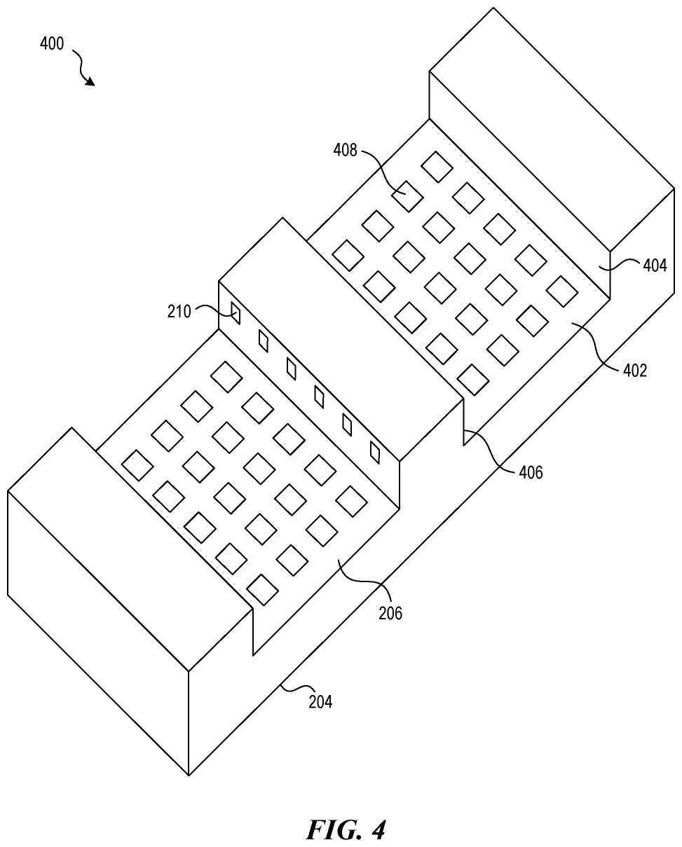

FIG. 4 illustrates a simplified schematic perspective view of a semiconductor device assembly 400 in accordance with an embodiment of the present technology. In aspects, the semiconductor device assembly 400 illustrated may correspond to a perspective view of the substrate 204 without the dies (e.g., dies 202 of FIG. 2) installed at the cavities 206.

In some implementations, the cavities 206 may be created such that they have a rectangular cross section. For example, the cavities 206 may include three surfaces: a bottom surface 402, a first side surface 404 normal with the bottom surface 402, and a second side surface 406 normal with the bottom surface 402 and parallel the first side surface 404. Although illustrated with a particular configuration, the cavities 206 may include any other configuration, including cavities 206 having a different cross section. Additionally, the substrate 204 may include a greater number of cavities 206 than shown (e.g., three, four, five, etc.).

The substrate 204 may include any number or configuration of connective elements to enable connections between the dies and the substrate 204. For example, the substrate 204 may include connective elements 210 located at one or both of the sides surfaces 404 or the side surfaces 406 of the cavities 206 and contact pads 408 located at the bottom surface 402 of one or more of the cavities 206. Any of the connective elements on the substrate 204 may electrically couple to a corresponding connective element on the dies through physical or contactless coupling.

As illustrated, the substrate 204 includes connective elements 210 located at a side surface 404 or a side surface 406. In some implementations, the connective elements 210 may be located at portions of the substrate 204 that are located between two cavities 206 to enable communication (e.g., through internal circuitry) between the connective elements 210 implemented at each of the cavities 206. The connective elements 210 may include any number of physical or contactless coupling elements, including those described with respect to FIGS. 3A-3C. In general, the connective elements 210 may correspond (e.g., in location or type) to connective elements located on the edge surfaces of dies (e.g., connective elements 208).

The substrate 204 may also include contact pads 408 located at the bottom surface of the cavities 206. The contact pads 408 may be implemented as conductive structures that couple directly or indirectly to internal or external traces, vias, lines, and other electrical connection structures to provide functionality (e.g., power, ground, input/output (I/O) signals) to a component coupled thereto. For example, the contact pads 408 may couple to internal circuitry to couple contact pads 408 at one of the cavities 206 to contact pads at another of the cavities 206. Alternatively or additionally, the contact pads 408 may couple to circuitry that connects the contact pads 408 to one or more external components, for instance, provided by or coupled to a PCB.

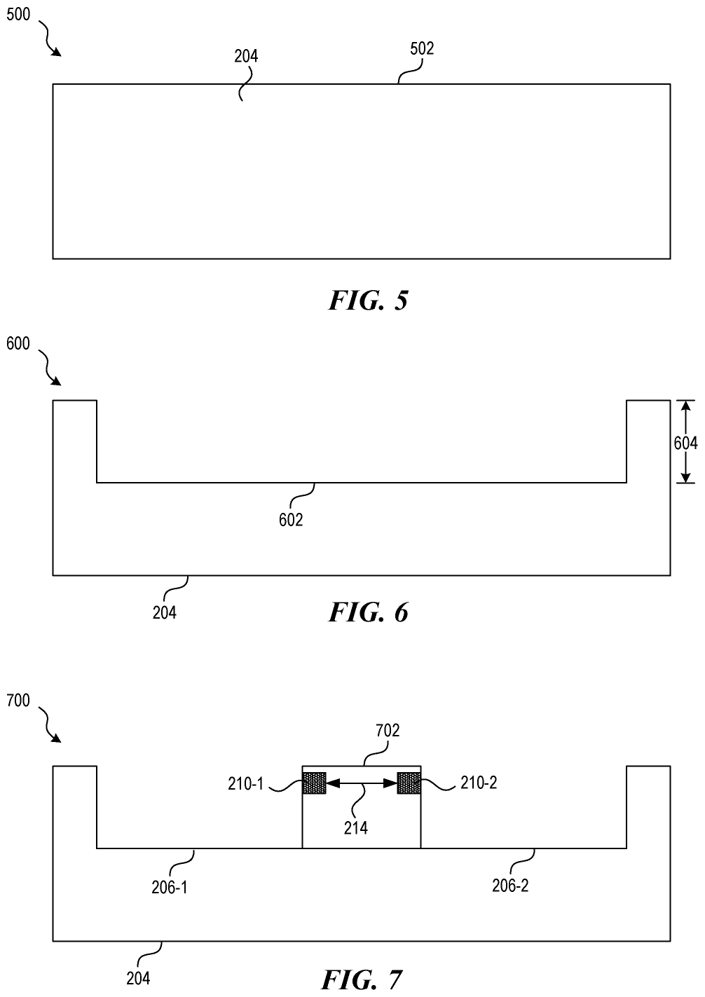

FIGS. 5 through 9 illustrate simplified schematic cross-sectional views of a series of fabrication steps of semiconductor device assemblies in accordance with an embodiment of the present technology. As illustrated in FIG. 5, the method may include a stage 500 for providing the substrate 204. The substrate 204 may be provided with a rectangular cross section. The substrate 204 may include an upper surface 502 at which circuitry is deposited. The substrate 204 may be composed of any semiconductor material, for example, silicon, germanium, silicon-germanium alloy, gallium arsenide, gallium nitride, etc.

As illustrated in FIG. 6, the method may include a stage 600 for etching the substrate 204 to create a single cavity 602. The cavity 602 implemented as a single rectangular cavity with a bottom surface large enough to implement multiple die-sized cavities (e.g., cavities 206 of FIG. 2). In some implementations, material may be deposited at the cavity 602 to create internal circuitry within the substrate 204, for example, contact pads (e.g., contact pads 408 of FIG. 4) or traces, vias, or lines coupling the contact pads. The cavity 602 may be etched in the substrate 204 using any appropriate technique, for example, wet etching, plasma etching, planarization, etc. In some implementations, photolithography may be used to create the cavity 602.

The cavity 602 may be etched such that a depth 604 of the cavity 602 is sufficient to mount one or more recessed dies in the cavity. For example, the cavity 602 may have a 604 that is greater than or equal to the thickness of the dies or the thickness of the dies and the connective structure (e.g., solder) used to mount the dies. In some implementations in which a stack of semiconductor dies is implemented in the cavity 602, the cavity 602 may have a depth equal to the thickness of the semiconductor stack. In aspects, the depth 604 of the cavity 602 may be designed such that an upper surface of the die mounted to the substrate 204 at the cavities 206 has a surface coplanar with the upper surface of the substrate 204 (e.g., upper surface 502 of FIG. 5), for instance, to provide a planar mounting surface for additional dies.

As illustrated in FIG. 7, the method may include a stage 700 for depositing material to create the cavities 206. The material may be deposited at a portion (e.g., or multiple portions) of the bottom surface of the single cavity 602 of FIG. 6 to create a structure 702 that separates two (e.g., or more) discrete cavities 206 (e.g., cavity 206-1 and 206-2). The cavities 206 may have a same of different depth, for example, based on the thickness of the dies implemented at each of the cavities 206. The material may include any combination of conductive and non-conductive materials (e.g., dielectric material). The material may be deposited through, for instance, chemical vapor deposition, physical vapor deposition, atomic layer deposition, spin coating, and/or other suitable techniques. The structure 702 may include a one or more layers of conductive and non-conductive material, such that the connective elements 210 (e.g., connective element 210-1 and connective element 210-2) may be implemented at the structure 702.

In addition to creating the connective elements 210, the structure 702 may include internal circuitry that creates the coupling 214 that connects the connective elements 210 (e.g., coupling connective element 210-1 and connective element 210-2). For example, layers of conductive material may be deposited to implement traces coupling the connective elements 210. The connective elements 210 may be developed by depositing layers of conductive and non-conductive material, for example, similar to the technique described with respect to FIGS. 3A-3C to create the connective elements 208. The structure 702 may be created such that a thickness of the structure 702 is equal to the depth of the cavities 206 (e.g., depth 604 of FIG. 6), which may provide a planar top surface to which one or more additional dies can be mounted.

It should be noted that although described with respect to a specific embodiment in which a large cavity (e.g., cavity 602 of FIG. 6) is etched and material is deposited to create discrete cavities 206, a semiconductor device in accordance with an embodiment of the present technology may be created through any number of additional or alternative methods. For example, etching may be used to create the discrete cavities 206 without first creating the single, large cavity 602. Etching and material deposition may be used to create the connective elements 210 and the circuitry connecting the connective elements. The connective elements 210 and the connecting circuitry may be disposed at the substrate 204 before or after the cavities 206 are etched.

In yet another embodiment, the cavities 206 and the structure 702 may be created by depositing material around the cavities 206 at the upper surface of the substrate without requiring any cavities (e.g., cavity 602 or cavities 206) to be etched into the substrate 204. The connective elements 210, the circuitry coupling the connective elements 210, and the various surfaces of the recessed cavities 206 may be created from the deposited material. Given that the cavities 206 are created on top of the original substrate 204, etching the substrate 204 may not be needed.

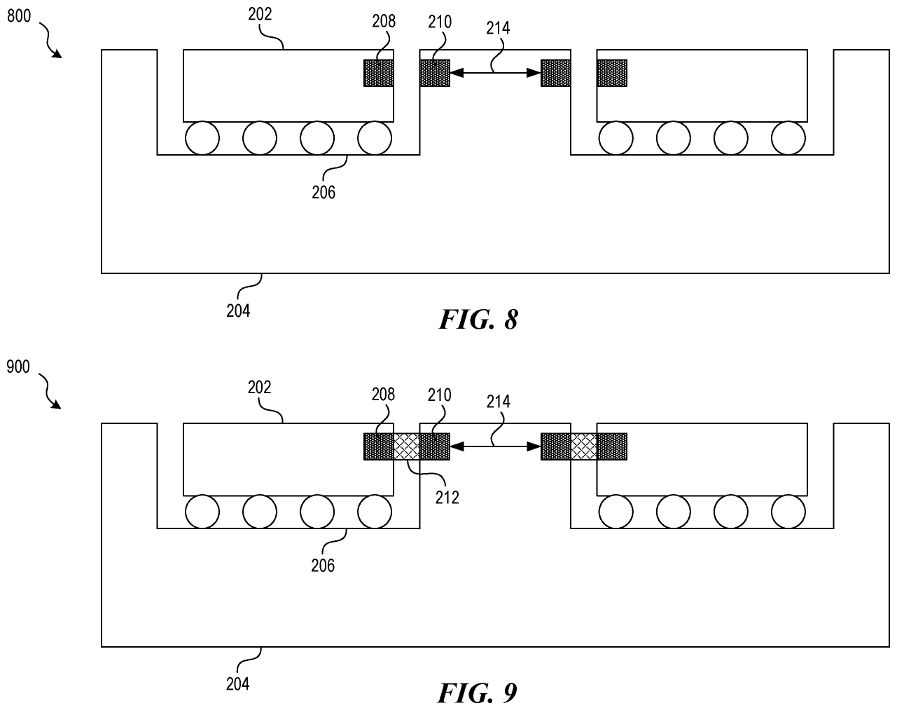

As illustrated in FIG. 8, the method may include a stage for assembling the dies 202 on the substrate 204. The dies 202 may be assembled at the cavities 206. In some implementations, the dies 202 may be assembled such that connective elements 208 at the dies 202 correspond to connective elements 210 at the substrate 204. Additionally, the dies 202 may include contact pads at a lower surface that align with contact pads at a bottom surface of the cavities 206. When assembled, the dies 202 may be partially or completely recessed in the substrate 204. For example, the dies 202 may be assembled at the cavities 206 such that an upper surface of the dies 202 recedes below, protrudes above, or is coplanar (e.g., flush) with an upper surface of the substrate 204.

In some implementations, the dies 202 may be replaced with die stacks such that multiple vertically stacked semiconductor dies are implemented at each cavity 206. In these implementations, one or more of the dies within each stack may include connective elements 208, and the substrate 210 may have connective elements 210 that correspond to each of the dies with connective elements 208. Additionally, connecting circuitry may be disposed between each of the connective elements 210 to create the coupling 214. In this way, the connective elements 210 or the connecting circuitry may be implemented at multiple vertical locations along the substrate 204. In other implementations, a single die within the die stack may include the connective elements 208 and signaling sent between the dies stack may be passed through the single die at which the connective elements 208 are located.

As illustrated in FIG. 9, the method may include a stage 900 for coupling the dies 202 to the substrate 204. At stage 900, interconnects 212 may be implemented between the connective elements 208 and the connective elements 210 to electrically couple the dies 202 (e.g., illustrated as the coupling 214). The interconnects 212 may include any number of connective couplings, including physical or contactless couplings. The process for coupling the dies 202 to the substrate 204 may vary based on the type of connective elements 208 and connective elements 210 (e.g., as described in FIGS. 3A-3C). For example, when the connective elements 210 are implemented as conductive contacts, the interconnects 212 may be connection structures implemented between the connective elements 208 and the connective elements 210, for example, solder. Alternatively, the interconnects 212 may be implemented as a wire, pillar, any other conductive structure.

In implementations that utilize inductors as the connective elements 208 and connective elements 210, the interconnect 212 may include a contactless inductive coupling. The coupling may include aligning the connective elements 208 and the connective elements 210 such that when a current is introduced in one of the connective elements 208 or the connective elements 210, a corresponding current is produced in the other of the connective elements 208 or the connective elements 210. This may include aligning inductive coils of the connective elements 208 and the connective elements 210 about a same central axis.

When the connective elements 208 and the connective elements 210 are instead implemented as optical elements or transceivers, the coupling may include aligning a transmitter located at one of the connective elements 208 or the connective elements 210 with a receiver at the other of the connective elements 208 or the connective elements 210. The transmitter and receiver may be aligned such that transmit signals (e.g., optical signals or wireless signals) from the connective elements 208 are received at a receiver of the connective elements 210, and vice versa.

In addition to coupling through the connective elements 208 and the connective elements 210, the dies 202 may couple through contact pads at the lower surface of the dies 202 and contact pads at the bottom surface of the cavities 206. The contact pads may be coupled through conductive structures (e.g., solder, copper pillars, etc.) that can carry electrical signals between the dies 202 and the substrate 204. In some implementations, the dies 202 may include TSVs that couple circuitry at an upper portion of the dies 202 to contact pads at the lower surface of the dies 202. The substrate 204 may similarly include TSVs that couple the contact pads at the bottom surface of the cavities 206 to internal or external circuit components coupled to the substrate 204 at the lower surface.

In addition to electrically coupling the dies 202 and the substrate 204, the conductive structures may physically couple the dies 202 to the substrate 204 at the cavities 206. In addition, or as an alternative to the conductive structures, the dies 202 may couple to the substrate 204 through adhesive applied at one or more of the surfaces of the dies 202 or the cavities 206. In some implementations, the semiconductor device assembly may include an underfill material between the dies 202 and the substrate 204 to support the mechanical coupling of the dies 202 and the substrate 204 or to insulate the electrical coupling of the dies 202 and the substrate 204.

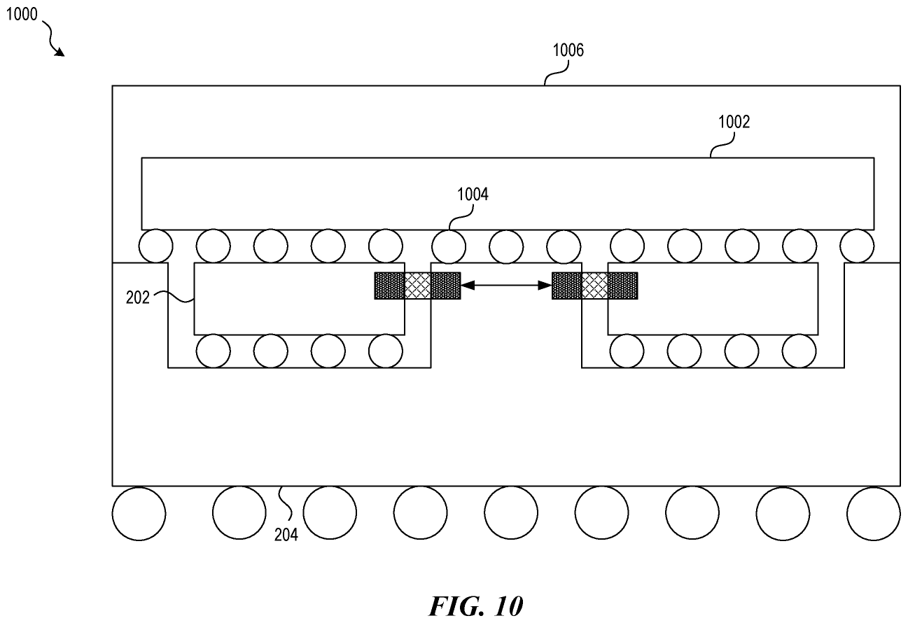

FIG. 10 illustrates a simplified schematic cross-sectional view of a semiconductor device assembly 1000 in accordance with an embodiment of the present technology. The semiconductor device assembly 1000 may correspond to a stacked semiconductor device including an additional semiconductor die 1002 mounted on the recessed semiconductor device assembly illustrated in FIG. 9.

The substrate 204 may correspond to a base substrate on which semiconductor dies are stacked, for example, in system in package applications. The upper surface of the substrate 204 and an upper surface of the recessed dies 202 may create a planar bonding surface for the additional die 1002 to be mounted on. The additional die 1002 may be the same or a different size (e.g., footprint) as the dies 202. For example, the additional die 1002 may be larger than the dies 202. In some implementations, the dies 202 may include memory dies and the additional die 1002 may include a logic die that control operations of the memory dies. Alternatively, the dies 202 and the additional die 1002 may include any other combination of semiconductor dies.

The additional die 1002 may be mounted to the substrate 204 or one or more of the dies 202. For example, the additional die 1002 may couple to contact pads at the upper surface of the dies 202 or contact pads at the upper surface of the substrate 204. Although illustrated as a single die, the die 1002 may include a vertical stack of dies or a set of dies implemented laterally along the upper surface of the substrate 204 or the dies 202.

The additional die 1002 may couple to the substrate 204 or the dies 202 through connection structures 1004 (e.g., solder joints, copper pillars, etc.) between a lower surface of the additional die 1002 and an upper surface of the dies 202 or the substrate 204. The connection structures 1004 may couple to contact pads at the lower surface of the additional die 1002. The connection structures 1004 may similarly couple to contact pads at an upper surface of the dies 202 or the substrate 204. As a result, the additional die 1002 may electrically couple to the dies 202 or the substrate 204 through the connection structures 1004. The additional die 1002 may include TSVs that couple from circuitry at the upper portion of the die 1002 to the contact pads at the lower surface of the die 1002.

The semiconductor device assembly 1000 may include an encapsulant 1006 that encapsulates at least a portion of the dies 202 or the die 1002. The encapsulant 1006 may protect the dies (e.g., dies 202 or die 1002) from environmental factors (e.g., moisture, particulates, static electricity, and physical impact). Once packaged, the semiconductor device assembly 1000 may be implemented within a system to provide various functionality.

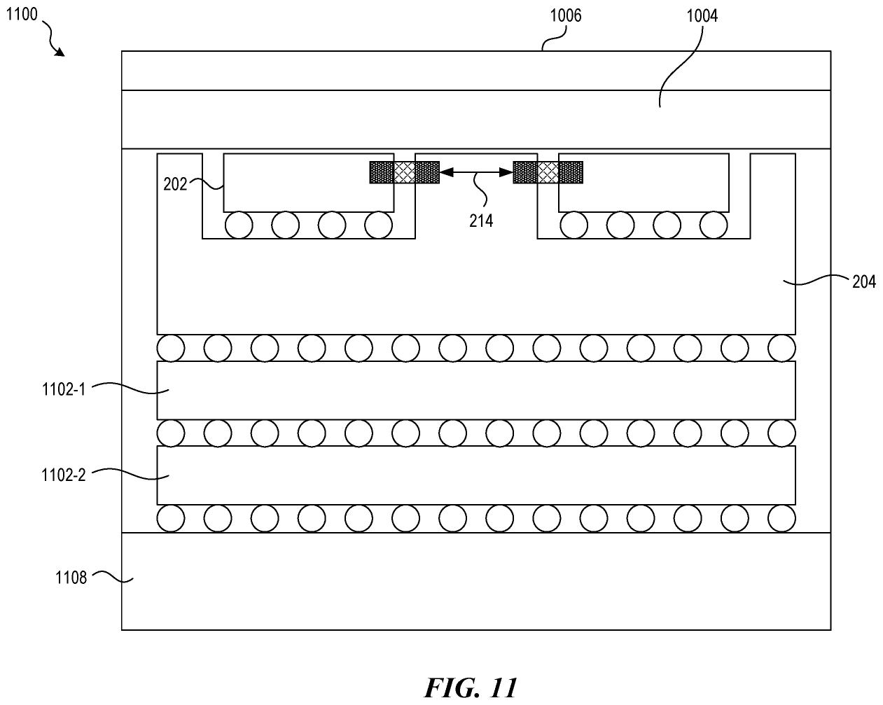

FIG. 11 illustrates a simplified schematic cross-sectional view of a semiconductor device assembly 1100 in accordance with an embodiment of the present technology. The semiconductor device assembly 1100 may correspond to a stacked semiconductor device that includes the recessed semiconductor device assembly illustrated in FIG. 9 mounted on the dies 1102 (e.g., die 1102-1 and 1102-2). The substrate 204 may be mounted on the dies 1102 through any number of connection structures. For example, the substrate 204 may include contact pads at the lower surface that couple with contact pads at an upper surface of the die 1102-1 through the connection structures. The substrate 204 may include TSVs that couple circuitry on the dies 202 to the contact pads at the lower surface of the substrate 204.

A lid 1104 may be provided at an upper surface of the vertical stack of semiconductor dies, for instance, at an upper surface of the substrate 204 or the dies 202. The lid 1104 may enclose the dies 202 within the substrate 204. The stack of dies may be packaged using an encapsulant 1106 that at least partially encapsulate the stack of semiconductor dies. The encapsulant 1106 may protect the dies (e.g., dies 202 or die 1002) from environmental factors (e.g., moisture, particulates, static electricity, and physical impact).

The packaged semiconductor device may be assembled onto a PCB 1108 that connects to one or more other system components. The packaged semiconductor device assembly may electrically couple to the one or more other system components to provide functionality to a system in which the semiconductor device is implemented. Implementing the dies 202 within the substrate 204 may reduce a vertical height of the stacked device. Additionally, the coupling 214 between the edge surface connections of the dies 202 may enable additional communication between the dies 202. Thus, the present technology may enable a compact and connected semiconductor device to be assembled.

Although the foregoing example semiconductor device assemblies have been illustrated and described as including a particular number of semiconductor dies, in other embodiments, assemblies can be provided with more or less semiconductor dies. For example, the semiconductor devices illustrated in FIGS. 2 through 11 could be replaced with semiconductor devices having any other number of semiconductor dies, mutatis mutandis.

In accordance with one aspect of the present disclosure, the semiconductor devices illustrated in the assemblies of FIGS. 2-11 could be memory dies, such as dynamic random-access memory (DRAM) dies, NOT-AND (NAND) memory dies, NOT-OR (NOR) memory dies, magnetic random-access memory (MRAM) dies, phase change memory (PCM) dies, ferroelectric random-access memory (FeRAM) dies, static random-access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

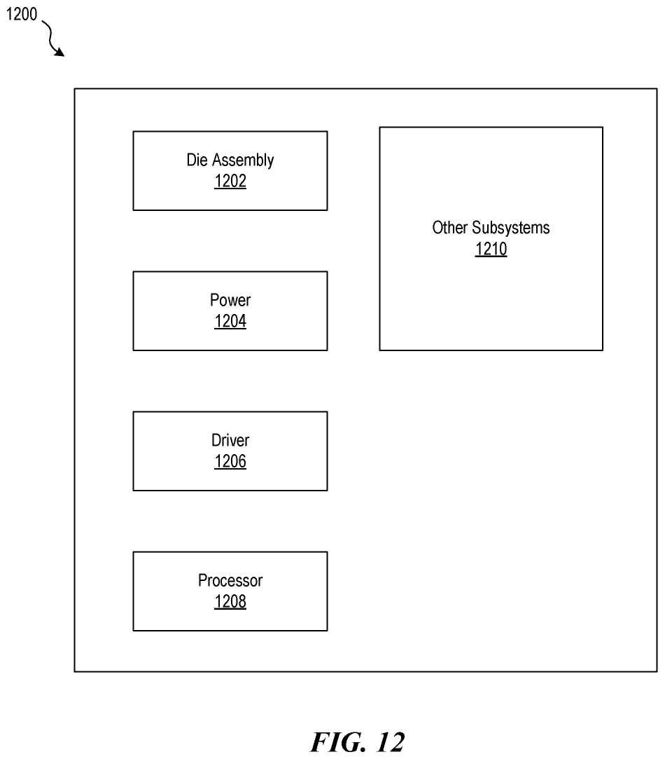

Any one of the semiconductor devices and semiconductor device assemblies described above with reference to FIGS. 2-11 can be incorporated into any of a myriad of larger and/or more complex systems, a representative example of which is system 1200 shown schematically in FIG. 12. The system 1200 can include a semiconductor device assembly 1202 (e.g., or a discrete semiconductor device), a power source 1204, a driver 1206, a processor 1208, and/or other subsystems or components 1210. The semiconductor device assembly 1202 can include features generally similar to those of the semiconductor devices described above with reference to FIGS. 2-11. The resulting system 1200 can perform any of a wide variety of functions, such as memory storage, data processing, and/or other suitable functions. Accordingly, representative systems 1200 can include, without limitation, hand-held devices (e.g., mobile phones, tablets, digital readers, and digital audio players), computers, vehicles, appliances and other products. Components of the system 900 may be housed in a single unit or distributed over multiple, interconnected units (e.g., through a communications network). The components of the system 1200 can also include remote devices and any of a wide variety of computer-readable media.

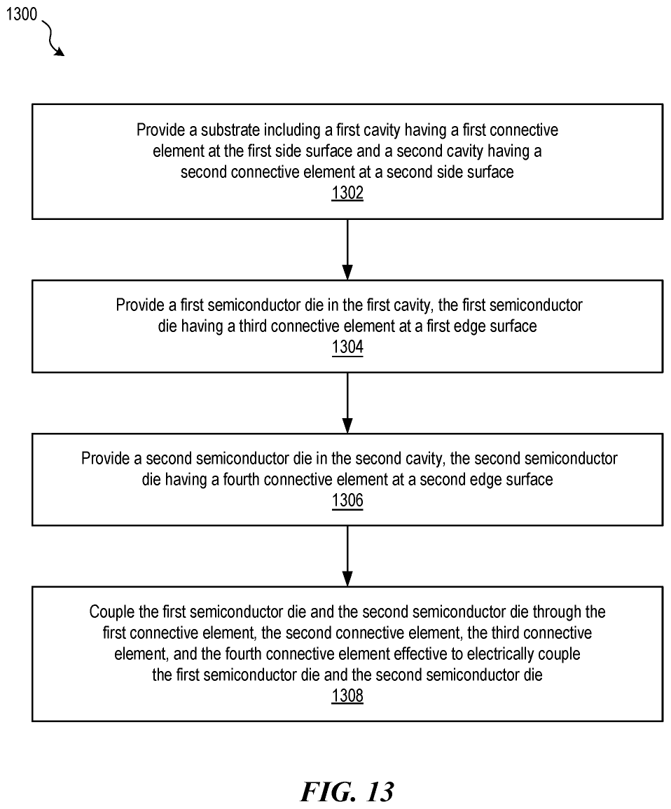

FIG. 13 illustrates an example method for fabricating a semiconductor device assembly in accordance with an embodiment of the present technology. The method 1300 may, for illustrative purposes, be described with respect to features, components, or elements of FIGS. 2-12. Although illustrated in a particular configuration, one or more operations of the method 1300 may be omitted, repeated, or reorganized. Additionally, the method 1300 may include other operations not illustrated in FIG. 13, for example, operations detailed in one or more other method described herein.

At 1302, a substrate 204 may be provided. The substrate 204 may include a first cavity 206-1 having a first connective element 210-1 at a first side surface 404. The substrate 204 may additionally include a second cavity 206-2 having a second connective element 208-2 at a second side surface 406. The cavities 206 may be created by etching a top surface 502 of the substrate 204. The cavities 206 may additionally or alternatively be created by depositing a layer of conductive material 304 and a layer of non-conductive material (e.g., a dielectric material 306) between the first cavity 206-1 and the second cavity 206-2. The deposition may create circuitry coupling the first connective element 210-1 to the second connective element 210-2.

At 1304, a first semiconductor die 202-1 may be provided. The first semiconductor die 202-1 may include a third connective element 208-1 at a first edge surface 308. The connective element 208-1 may include a conductive contact 302, and inductor 310, an optical element 312, or a transceiver. At 1306, a second semiconductor die 202-2 may be provided. The second semiconductor die 202-2 may include a fourth connective element 208-2 at a second edge surface 308. The connective element 208-1 may include a conductive contact 302, and inductor 310, an optical element 312, or a transceiver.

At 1308, the first semiconductor die 202-1 and the second semiconductor die 202-2 may be coupled through the first connective element 210-1, the second connective 210-2 element, the third connective element 208-1, and the fourth connective element 208-2. The coupling 214 may be effective to electrically couple the first semiconductor die 202-1 and the second semiconductor die 202-2. The first connective element 210-1 and the third connective element 208-1 may electrically couple through interconnects 212. The interconnects 212 may include a conductive structure (e.g., solder joint), an inductive coupling, a wireless connection, or an optical connection.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a substrate including:
a first cavity having a first connective element at a first side surface of the first cavity; and
a second cavity having a second connective element at a second side surface of the second cavity;
a first semiconductor die disposed in the first cavity and having a third connective element at a first edge surface of the first semiconductor die; and
a second semiconductor die disposed in the second cavity and having a fourth connective element at a second edge surface of the second semiconductor die,
wherein the first semiconductor die and the second semiconductor die are electrically coupled through the first connective element, the second connective element, the third connective element, and the fourth connective element.

2. The semiconductor device assembly of claim 1, further comprising circuitry internal to the substrate and coupling the first connective element to the second connective element.

3. The semiconductor device assembly of claim 1, wherein:
the first connective element and the third connective element comprise a conductive contact; and
the semiconductor device assembly further comprises a solder joint coupling the first connective element and the third connective element.

4. The semiconductor device assembly of claim 1, wherein:
the first connective element and the third connective element comprise an inductor; and
the first connective element and the third connective element electrically couple through an inductive coupling.

5. The semiconductor device assembly of claim 1, wherein:
the first connective element and the third connective element comprise an optical element; and
the first connective element and the third connective element electrically couple through an optical connection.

6. The semiconductor device assembly of claim 1, wherein an upper surface of the first semiconductor die is flush with or recessed from an upper surface of the substrate.

7. The semiconductor device assembly of claim 1, further comprising a third semiconductor die mounted to at least one of: an upper surface of the first semiconductor die, an upper surface of the second semiconductor die, an upper surface of the substrate, or a lower surface of the substrate.

8. The semiconductor device assembly of claim 1, wherein the first and second connective elements are spaced from an upper surface of the substrate.

9. The semiconductor device assembly of claim 1, wherein:
the substrate further includes a fifth connective element at a bottom surface of the first cavity; and
the first semiconductor die has a sixth connective element at a bottom surface of the first semiconductor die, the sixth connective element coupled with the fifth connective element effective to electrically couple the first semiconductor die and the substrate.

10. The semiconductor device assembly of claim 1, further comprising a third semiconductor die disposed in the first cavity below the first semiconductor die.

11. A method of assembly for a semiconductor device, comprising:
providing a substrate including:
a first cavity having a first connective element at a first side surface of the first cavity; and
a second cavity having a second connective element at a second side surface of the second cavity;
providing a first semiconductor die at the first cavity, the first semiconductor die having a third connective element at a first edge surface of the first semiconductor die;
providing a second semiconductor die at the second cavity, the second semiconductor die having a fourth connective element at a second edge surface of the second semiconductor die; and
coupling the first semiconductor die and the second semiconductor die through the first connective element, the second connective element, the third connective element, and the fourth connective element effective to electrically couple the first semiconductor die and the second semiconductor die.

12. The method of claim 11, further comprising etching the substrate to create the first cavity and the second cavity.

13. The method of claim 11, further comprising depositing a layer of conductive material and a layer of non-conductive material at the substrate between the first cavity and the second cavity to create circuitry coupling the first connective element and the second connective element.

14. The method of claim 11, further comprising coupling the first connective element and the third connective element through a solder joint to electrically couple the first semiconductor die and the substrate.

15. The method of claim 11, further comprising coupling the first connective element and the third connective element through an inductive coupling to electrically couple the first semiconductor die and the substrate.

16. The method of claim 11, further comprising coupling the first connective element and the third connective element through an optical connection to electrically couple the first semiconductor device to the substrate.

17. A substrate comprising:
a first cavity recessed in a top surface of the substrate, the first cavity having a first connective element exposed at a side surface of the first cavity;
a second cavity recessed in the top surface of the substrate, the second cavity having a second connective element exposed at a side surface of the second cavity; and
circuitry internal to the substrate and coupling the first connective element and the second connective element.

18. The substrate of claim 17, wherein the first connective element comprises: a conductive contact, an inductor, or an optical element.

19. The substrate of claim 17, wherein the substrate further includes a third connective element exposed at a bottom surface of the first cavity.

20. The substrate of claim 19, wherein the first cavity and the second cavity have different depths.
